(19) United States
(12) Patent Application Publication
(10) Pub. No.: US 2013/0074921 A1
(43) Pub. Date: Mar. 28, 2013

(54) Low-Resistance Back Contact For Photovoltaic Cells

(71) Applicants: Ching Wan Tang, Brighton, NY (US); Wei Xia, Rochester, NY (US); Hsiang Ning Wu, Rochester, NY (US); Hao Lin, Rochester, NY (US)

(72) Inventors: Ching Wan Tang, Brighton, NY (US); Wei Xia, Rochester, NY (US); Hsiang Ning Wu, Rochester, NY (US); Hao Lin, Rochester, NY (US)

(21) Appl. No.: 13/629,064

(22) Filed: Sep. 27, 2012

Related U.S. Application Data
(60) Provisional application No. 61/540,264, filed on Sep. 28, 2011.

(51) Int. Cl. H01L 31/0216; H01L 31/0224

(52) U.S. Cl. 136/256

(57) ABSTRACT

Photovoltaic cells (e.g., p-CdTe thin film photovoltaic cells) comprising a back contact buffer layer that makes low-resistance electrical contact to the p-type semiconductor material of the cell (e.g., CdTe). The back contact buffer material comprises Cu and Te.

### CROSS-REFERENCE TO RELATED APPLICATIONS

This application claims priority to U.S. provisional patent application No. 61/540,264, filed Sep. 28, 2011, the disclosure of which is incorporated herein by reference.

### FIELD OF THE INVENTION

The present invention generally relates to the field of photovoltaic cells and more particularly relates to the structure and production of thin film photovoltaic cells. In particular, the present invention relates to the formation of a low-resistance, non-rectifying back contact to a p-type semiconductor (e.g., p-CdTe).

### BACKGROUND OF THE INVENTION

Thin film photovoltaic cells based on polycrystalline n-CdS/p-CdTe heterojunction have gained intensive attention for application in large-scale, terrestrial electricity generation. However, further improvements in cell performance and fabrication methods are necessary for them to surpass the conventional crystalline silicon photovoltaic cells.

An outstanding problem in achieving high-efficiency CdS/CdTe cells is the formation of a low-resistance contact to p-CdTe. According to the traditional theory of ohmic contact formation, a metal forming an ohmic contact to p-CdTe should have its Fermi level aligned with the top of the CdTe valence band. However, because p-CdTe has a work function as high as 5.7 eV, most common metals are incapable of matching the work function and thus are not useful for making ohmic contact to p-CdTe.

### BRIEF SUMMARY OF THE INVENTION

The present invention provides a device structure for photovoltaic cells having a back contact buffer layer comprising tellurium and copper, and methods of making same. The photovoltaic cells of the present invention feature a low-resistance electrical contact to p-CdTe, which results in an a significantly high fill factor (˜78%) as well as a high solar power conversion efficiency (˜14%).

In an aspect, the present invention provides a method for producing a low-resistance back contact to a p-type semiconductor (e.g., p-CdTe). As a consequence, photovoltaic cells (e.g., CdS/CdTe cells) having desirable properties have been produced. This back contact comprises Te/Cu layer as the buffer, which can be produced by sequential deposition of a layer of Te followed by Cu onto p-CdTe. Separately a metal layer on top of the Te/Cu provides the back electrode. Additionally, thermal activation is performed on the completed cell in order to produce the desired low-resistance back contact and substantial device performance enhancement.

In an embodiment, the photovoltaic cell comprises a p-type semiconductor material having a thickness of 0.5 microns to 2 microns, a back contact buffer material in contact with the p-type semiconductor material, and a back electrode material in contact with the back contact buffer layer, wherein the back contact buffer material comprises tellurium and copper. In another embodiment, the photovoltaic cell comprises a p-type semiconductor material, a back contact buffer material in contact with the p-type semiconductor material, and a back electrode in contact with the buffer material, wherein the buffer material comprises tellurium and copper, wherein the ratio of copper to tellurium molar ratio is from 1×10⁻⁴ to 0.3. In an embodiment, the p-type semiconductor material, the back contact buffer material, and the back electrode material are present as layers, and the photovoltaic cell further comprises: a substrate, where the substrate is at least semitransparent; a front electrode layer, wherein the front electrode is at least semitransparent; optionally, a front buffer layer; and an n-type semiconductor layer; and the photovoltaic cell comprises the following components, in sequence: a) the substrate; b) the front electrode; c) optionally, the front buffer layer; d) the n-type semiconductor layer; e) the p-type semiconductor layer; e) the back contact buffer layer; and f) the back electrode.

In an embodiment, the present invention provides a device structure for CdS/CdTe cells, comprising the following components in sequence: a) a substrate, e.g., a semitransparent substrate such as soda-lime glass, b) a front electrode, e.g., semitransparent front electrode such as a conductive fluorine-doped tin oxide (FTO), c) a layer of a n-type semiconductor, e.g., CdS, having a thickness of 50 nm to 200 nm, d) a layer of p-type semiconductor, e.g., CdTe, having a thickness of 1 μm to 6 μm, e) a back contact buffer layer, e.g., a layer of Te having a thickness of 10 nm to 1000 nm and a layer of Cu having a thickness of 0.05 nm to 10 nm, and g) a back electrode, e.g., nickel.

In an embodiment, the present invention provides a method for fabricating CdS/CdTe cells with a back contact buffer layer between the p-type semiconductor, e.g., CdTe, layer and the back electrode, wherein the buffer layer comprises a Te layer and a Cu layer deposited on the CdTe layer by physical vapor deposition.

In embodiment, the back contact buffer layer is formed by depositing a bi-layer having a Te layer and a Cu layer by physical vapor deposition. Additionally, a thermal annealing step at a temperature of at least 200° C. after the cell is completed with the back electrode to activate the buffer layer.

### BRIEF DESCRIPTION OF THE FIGURES

FIG. 1. Schematic illustration of an embodiment of a CdS/CdTe cell with the back contact buffer.

FIG. 2. Representative current-voltage characteristics of CdS/CdTe cells with various back contact buffer layers: no buffer layer, Te-rich layer created using a nitric/phosphoric acid (NP) solution, 100 nm Te, and 100 nm Te plus 1.1 nm Cu.

FIG. 3. Representative current-voltage characteristics of CdS/CdTe cells with different thickness of Te buffer layer.

FIG. 4. Representative current-voltage characteristics of CdS/CdTe cells with different thickness of Cu buffer layer.

FIG. 5. Representative current-voltage characteristics of CdS/CdTe cells annealed at different temperatures for the same duration.

FIG. 6. Representative current-voltage characteristics of CdS/CdTe cells annealed at the same temperature for different duration.

FIG. 7. Representative current-voltage characteristics of ultra-thin CdS/CdTe cells with different thickness of CdTe layer.

FIG. 8. Representative current-voltage characteristics of CdS/CdTe cells with Te/Cu back contact of different Cu/Te molar ratios.

FIG. 9. Example of device performance of CdS/CdTe cells with Te/Cu and Te back contact before and after thermal stress test at 200° C. for 1˜9 hours.

### DETAILED DESCRIPTION OF THE INVENTION

The present invention provides a device structure for photovoltaic cells having a back contact buffer material comprising tellurium and copper. The present invention also provides a method for fabricating such photovoltaic cells.

The present invention features the following advantages:
a) The Te/Cu buffer material provides a low-resistance electrical contact to p-type semiconductor layers (e.g., a p-CdTe layer);
b) Improved photovoltaic device performance is achieved: fill factor (FF) ˜78%, open circuit voltage (V_{OC}) ˜840 mV, and power conversion efficiency (η) ˜14%;
c) The device fabrication process is simplified by using only in-line vapor deposition processes without any additional wet process steps;
d) The Te/Cu buffer material is particularly useful for the fabrication of ultra-thin photovoltaic cells because it reduces the formation of electrical shunts;
e) The Cu/Te ratio can be readily controlled to achieve optimum cell efficiency and operational stability; and
f) A wide process window is available because of the large layer thickness tolerance for the Te/Cu buffer material.

In an aspect, the present invention provides photovoltaic cells (e.g., CdS/CdTe photovoltaic cells) having a back contact buffer material comprising tellurium and copper. Without intending to be bound by any particular theory it is considered that the back contact buffer material provides ohmic contact to the CdTe material and can prevent excess copper (which can lead to cell failure) from diffusing into CdTe and CdS and CdTe materials of the cells.

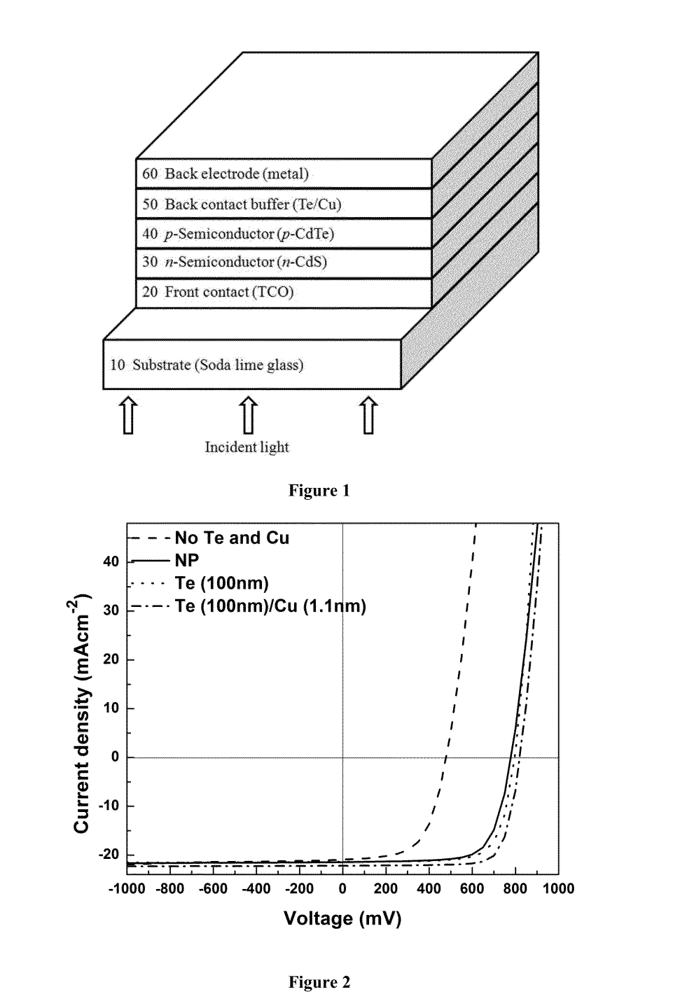

In an embodiment, the present invention provides a thin film photovoltaic cell which comprises of the following components, in sequence: a) a semitransparent substrate (e.g., soda-lime glass), b) a semitransparent front electrode (e.g., FTO), c) a layer of n-type semiconductor material (e.g., n-CdS), d) a layer of p-type semiconductor material (e.g., p-CdTe), e) a back contact buffer material comprising tellurium and copper (e.g., a bi-layer having a Te layer and a Cu layer), and f) a back electrode material (e.g., nickel). In an embodiement, the cell consists of the components. The schematic illustration of a device structure of a CdS/CdTe cell is shown in FIG. 1.

The substrate can be fabricated from a variety of materials. The substrate is at least semitransparent. By semitransparent it is meant that the substrate has a transparency of 50% to 95% over the wavelength region between 300 nm and 1000 nm. In an embodiment, soda-lime glass, which is inexpensive, is employed as the substrate. The substrate can be planar or non-planar. The substrate (e.g., layer 10 of the CdS/CdTe cells depicted graphically in FIG. 1) provides mechanical strength for the photovoltaic cell and allows light to pass through it. Moreover, it should also be thermally stable over the process temperature range for the photovoltaic cell fabrication (between 400° C. and 600° C.). Any substrates meeting these two requirements can be used for CdS/CdTe cells in this invention. Before the substrate is used, it is cleaned, for example, by mechanical scrubbing and sonication to remove any trace of organic residues and particles.

Disposed between the substrate (e.g., layer 10 in FIG. 1) and n-semiconductor material (e.g., layer 30 in FIG. 1) is a front electrode (e.g., layer 20 in FIG. 1). The front electrode can be fabricated from a variety of materials. Examples of suitable materials include transparent conducting oxides (TCO) such as fluorine-doped tin oxide, indium tin oxide, aluminum-doped zinc oxide, and cadmium tin oxide. In an embodiment, fluorine-doped tin oxide (FTO) is employed as the front electrode. It is desirable the front electrode be semitransparent over the wavelength region between 300 nm and 1000 nm and electrically conducting with a sheet resistance smaller than 100 ohm/square. It should also be stable over the process temperature for the photovoltaic cell fabrication.

An n-type semiconductor material (e.g., layer 30 in FIG. 1) acts as a window (e.g., a window layer) and forms a heterojunction with a p-type semiconductor material (e.g., layer 40 in FIG. 1). It is preferable the n-type semiconductor material be CdS. CdS has a larger bandgap (2.40 eV) than that of p-CdTe (1.45 eV). In addition, the lattice mismatch between n-CdS and p-CdTe is small (9%). Other suitable n-type semiconductor materials include, for example, CdSe, CdSₓSe₁₋ₓ, Cd₁₋ₓZnₓS and ZnS, where x is 0 to 1, including all values to 0.001 and ranges therebetween. A class of suitable n-type semiconductor materials is n-type metal oxides, such as ZnO, indium oxide, gallium oxide, indium gallium oxide, and indium gallium zinc oxide.

The n-type semiconductor material can be present as a thin film. The n-type semiconductor material (e.g., CdS) can be deposited as a thin film (e.g., on the top electrode) by various methods such as sputtering, thermal evaporation (e.g., resistive heating evaporation), chemical bath deposition, vapor transport deposition (VTD) and close-space sublimation (CSS). The thickness of CdS can be 50 nm to 200 nm, including all values to the nm and ranges therebetween. For example, the thickness is approximately 100 nm. For n-type materials with higher transparency in the visible region serving as the window layer (e.g., in CdTe solar cells), the layer thickness range can be extended to 50 nm to 200 nm, including all values to the nm and ranges therebetween.

A p-type semiconductor material (e.g., layer 40 in FIG. 1) is an absorbing material (e.g., an absorbing layer). This layer forms a heterojunction with the n-type semiconductor material (e.g., a CdS layer). It is desirable the p-type semiconductor material absorbs radiation having wavelengths in the solar spectrum. It is preferable the p-type semiconductor material is CdTe. CdTe has a high absorption coefficient (between10⁴ and 10⁵ cm⁻¹) and an ideal bandgap that matches well with the solar spectrum. Examples of suitable p-type semiconductor materials include ZnTe, Cd₁₋ₓZnₓTe, Cd₁₋ₓHgₓTe, Cd₁₋ₓMgₓTe, and Cd₁₋ₓMnₓTe, where x is 0 to 1, including all values to 0.001 and ranges therebetween. Other examples of suitable p-type semiconductor materials include copper indium gallium selenide (CIGS), copper indium selenide (CIS), and copper indium selenide (CIS).

The p-type semiconductor material can be present as a thin film. The p-type semiconductor material (e.g., CdTe) can be deposited as a thin film by a variety of methods such as CSS, vapor-transport deposition (VTD), sputtering and thermal evaporation (e.g., resistive heating evaporation), with CSS being a preferred method. The thickness of the p-type semiconductor layer is typically in the range of 0.5 micron to 6 microns, including all values to the 0.1 micron and ranges therebetween. In an embodiment, the p-type semiconductor layer is CdTe and has a thickness of 0.5 micron to 6 microns, including all values to the 0.1 micron and ranges therebetween.

The materials described herein can be present as thin films. The films can be continuous. The films can be free of pinhole defects. The films can be planar or non-planar. When the materials are present as thin films the photovoltaic cell is a thin-film photovoltaic cell. Thin films can be present in a crystalline morphology (e.g., as in crystalline or polycrystalline film) or in an amorphous morphology (e.g., as in a glassy polymeric film). Crystalline, amorphous, or a combination thereof, thin films can be used to produce a thin-film photovoltaic cell.

In an embodiment, the photovoltaic cell is an ultrathin photovoltaic cell. In this embodiment, the p-type semiconductor material (e.g., CdTe) layer has a thickness of 0.5 micron to 2 microns, including all integer values to the 0.1 micron and ranges therebetween.

Disposed between the p-type semiconductor material (e.g., CdTe) (e.g., layer 40 in FIG. 1) and the back electrode (e.g., layer 60 in FIG. 1) is the back contact buffer material (e.g., layer 50 in FIG. 1). This material has the necessary work function and capability of lowering the energy barrier at p-semiconductor/back electrode interface to facilitate electrical charge (e.g., hole) transfer between the electrode and the p-type semiconductor. The back contact buffer material comprises Te and Cu and forms a low-resistance electrical contact to p-CdTe.

The back contact buffer material can be present as a thin film (or a bilayer film comprising a layer of tellurium and a layer of copper). The back contact buffer layer (e.g., Te and Cu layers) can be deposited on top of the p-type semiconductor material (e.g., CdTe) by various physical vapor deposition methods such as, for example, DC sputtering, thermal evaporation (e.g., resistive heating evaporation), and e-beam deposition.

In an embodiment, the back contact buffer layer is a bi-layer structure (a Te layer and a Cu layer). The thickness of Te (e.g., a Te layer) ranges from 10 to 1000 nm, including all integer values to the nanometer and ranges therebetween, and the thickness of Cu is in the range of 0.05 nm to 10 nm, including all values to the 0.01 nanometer and ranges therebetween. In an embodiment, the Te layer is in contact with the p-type semiconductor material. In an embodiment, the back contact buffer layer comprises a bi-layer structure. In another embodiment, the back contact buffer layer consists of a bi-layer structure. In yet another embodiment, the back contact buffer layer consists essentially of a bi-layer structure. In an embodiment, the back contact buffer layer is a mixed film comprising Te and Cu, where the Cu is uniformly or non-uniformly distributed in a Te matrix.

The Cu to Te molar ratio is from 1×10⁻⁴ to 0.3, including all values to the 0.0001 and ranges therebetween. The preferred range of Cu to Te molar ratio is from 5×10⁻⁴ to 0.1.

A back electrode (e.g., layer 60 in FIG. 1) is the electrode that is in contact with the Cu/Te buffer layer (e.g., layer 50 in FIG. 1). In an embodiment, Ni is used as the back electrode. Other suitable back electrode materials include, for example, Mo, Au, Cr, Fe, Ni—Al alloy, and stainless steel. The back electrode can be deposited by various methods such as, for example, DC sputtering, thermal evaporation (e.g., resistive heating evaporation), and e-beam deposition.

Materials used to fabricate the photovoltaic cell can be obtained from commercial sources. Such materials can be prepared using methods known in the art.

In an aspect, the present invention provides a method for making a photovoltaic cell (e.g., a CdS/CdTe photovoltaic cell) having a back contact buffer layer having tellurium and copper. The methods comprise a step of annealing the cell after deposition of the back contact buffer layer and metal contact.

In an embodiment, the steps of the method comprise: a) depositing a front electrode on a substrate, b) depositing n-type semiconductor (e.g., CdS) on the front electrode from a), c) depositing p-type semiconductor (e.g., CdTe) on the n-type semiconductor from b), d) depositing a back contact buffer material comprising tellurium and copper on the p-type semiconductor from c); e) depositing a back electrode on the back contact buffer material from d) to form a photovoltaic cell, and f) annealing the photovoltaic cell to a temperature of at least 200° C.

The materials used in the photovoltaic cell can be deposited by methods known in the art. For example, layers (e.g., continuous films) of the various materials can be deposited by methods such as CSS, VTD, sputtering and thermal evaporation.

In embodiment, all of the steps of the method are dry (i.e., no wet processing steps are required). In an embodiment, all of the steps in the process are carried out under vacuum. Optionally, all of the steps can be carried out in the same apparatus.

Without intending to be bound by any particular theory, it is considered that a post-deposition heat treatment is generally necessary to produce efficient CdS/CdTe cells. In the case of CdS/CdTe cells, a particularly useful treatment is to subject CdS/CdTe stack to CdCl₂ vapor at a temperature between 380° C. and 450° C. for a duration of 2 minutes to 20 minutes. CdCl₂ treatment has been shown to improve the crystalline quality of CdTe and CdS layers.

The back contact buffer layer is continuous. In an embodiment, the back contact buffer layer is free from detectible pin-hole defects. Pin hole defects can be detected using, for example, microscopy (such as scanning electron microscopy) and electrical testing. In an embodiment, the back contact buffer material is formed by first depositing a layer of tellurium and then depositing a layer of copper to form a bi-layer back contact buffer layer. In another embodiment, the back contact buffer material is formed by first depositing a layer of copper and then depositing a layer of tellurium to form a bi-layer back contact buffer layer. In embodiment, the back contact buffer material is produced by simultaneously depositing Te and Cu to form a mixed film with a specific Cu to Te ratio.

After the photovoltaic cell is completed with deposition of the back electrode, the cell is subjected to an annealing process to activate the Te/Cu buffer layer. For example, the annealing step can be carried out by heating the cell to a temperature of at least 200° C. The thermal annealing on Te/Cu buffer layer can be carried out at a temperature ranging from 200° C. to 350° C., including all integer ° C. values and ranges therebetween, for a duration of 0.1 minute to 60 minutes, including all values to the 0.1 minute and ranges therebetween. The thermal annealing step can be carried out, for example, in a glass tube heated by a tube furnace, where a steady flow of inert gas such as nitrogen is maintained in the glass tube. In another example, the thermal annealing step can by carried out by irradiating the photovoltaic cell directly or indirectly using a heating lamp or laser continuously or intermittently. Cumulative heating with progressively increasing temperature and duration can also be carried out on the photovoltaic cell to achieve the optimal thermal activation and device performance.

Devices fabricated according to the present invention exhibit improved performance when compared to other photovoltaic devices. For example, devices with a back contact buffer layer comprising tellurium and copper exhibit improved performance relative to devices fabricated without such back contact buffer layers or devices fabricated using wet-processing methods, such as the NP method. Examples of improved performance include, but are not limited to, increased current density, open circuit voltage, fill factor, and/or efficiency.

The photovoltaic cells can exhibit an efficiency of at least 11%. In various embodiments, the photovoltaic cells exhibit an efficiency of at least 12%, at least 13%, or at least 14%.

In an aspect, the present invention provides a method of improving the electrical contact between a semiconducting material and an electrode material. In an embodiment, the method improves the electrical contact between a p-type semiconductor layer and metal electrode layer in a photovoltaic cell by depositing a back contact buffer layer on the p-type semiconductor layer and subsequently depositing a back electrode layer such as a metal layer.

In an aspect, the present invention provides a system for generating electrical energy. In an embodiment, the present invention provides a solar cell comprising the photovoltaic cells of the present invention, an electrical connection connected to the front electrode and an electrical connection to the back electrode. In another embodiment, the system comprises a plurality of photovoltaic cells connected electrically in series and/or parallel.

In an aspect, the photovoltaic cells of the present invention are used to generate electricity by converting photons to electrical charge carriers and by producing a voltage, which can, for example, drive an external load (e.g., a resistor). For example, a photovoltaic cell of the present invention can be used to generate electricity by impinging photons of the appropriate wavelength (e.g., sunlight) on the cell resulting in the generation of charge carriers and thus, electrical current.

The following examples are presented to illustrate the present invention. They are not intended to limiting in any manner.

### EXAMPLE 1

This example provides a comparison of CdS/CdTe cells with and without a Te/Cu back contact buffer layer.

CdS/CdTe cells were fabricated according to the procedure as following: a) FTO coated soda lime glass was cleaned by mechanical scrubbing and ultra-sonic cleaning, b) A layer of 200-nm CdS film was deposited on top of the glass substrate using a VTD method described by Moutinho et al. (J. Vac. Sci. Technol. A, 13 (1995) 2877), c) A layer of 5-μm CdTe film was deposited on top of CdS using a CSS method described by Tyan et al. (Sol. Cells, 23 (1988) 19), d) Following the CSS deposition of CdTe, a vaporous cadmium chloride (VCC) treatment was applied on substrate/FTO/CdS/CdTe stack layers according to the procedure described by McCandless et al. (Prog. Photovoltaics Res. Appl., 7 (1999) 21), and e) After VCC treatment, the cell was completed by depositing a layer of 200-nm Ni on top of CdTe by DC sputtering. For cells with the back contact buffer, a layer of 100-nm Te and a layer of 1.1-nm Cu were deposited on top of CdTe in sequence by DC sputtering prior to the deposition of back electrode. For the control cell, CdTe film was subjected to NP treatment (Li et al., J. Vac. Sci. Technol. A 17 (1999) 805) for 25 seconds prior to the deposition of Ni electrode. In the end, the cell was subjected to an annealing process at 240° C. for 20 seconds in N₂.

The current-voltage (J-V) characteristics of CdS/CdTe cells were measured using a Keithley source meter (Model 2400) and a tungsten-lamp-based solar simulator (Solux 3SS4736-50 W solar simulator). The solar simulator was calibrated with a silicon photodiode (Hamamatsu S 1787-12). The incident light intensity on the CdS/CdTe cells was 80 mW/cm². The values of the current density were corrected by integrating the photo-response of the cells with AM 1.5 solar spectrum. Spectral response measurements were obtained using a calibrated ¼ m monochromator (ARC SpectroPro 275).

TABLE 1
Device performances of CdS/CdTe cells with
different back contact buffer layers

| Back contact | Back contact | Jsc | Voc | FF | η |
|---|---|---|---|---|---|
| buffer/process | electrode | (mAcm⁻²) | (mV) | (%) | (%) |
| None | Ni | 20.9 | 478 | 60.5 | 6.0 |
| NP | Ni | 21.5 | 780 | 71.5 | 12.0 |
| Te | Ni | 21.4 | 800 | 73.9 | 12.7 |
| Te/Cu | Ni | 22.2 | 820 | 77.6 | 14.1 |

FIG. 2 exhibits the photo J-V characteristics of CdS/CdTe cells with and without the back contact buffer layer. The device performances of these cells are listed in Table 1. Compared with the cell without the back contact buffer layer, the cells with either Te or Cu/Te back contact buffer layer showed substantial improvement in cell efficiency. Compared with the cell with the NP treatment, the cell with Te/Cu the back contact buffer shows improved efficiency.

### EXAMPLE 2

This example shows the Effects of Te and Cu thickness on device performances of CdS/CdTe cells.

CdS/CdTe cells were fabricated according to the same procedure as Example 1, except for step e, which was modified as follows: e) After VCC treatment, a layer of Te with a thickness ranging from 0 to 300 nm and a layer Cu with a thickness ranging from 0.3 to 9.0 nm were deposited in sequence on top of CdTe by DC sputtering. The cells were then completed by depositing a layer of 200-nm Ni on top of Te/Cu buffer layer and subsequently subjecting the cells to an annealing process at 240° C. for 20 seconds in N₂ ambient.

TABLE 2
Device performances of CdS/CdTe cells with different thickness of Te.

| Back contact buffer | | Back contact | Jsc | Voc | FF | η |
|---|---|---|---|---|---|---|
| Te (nm) | Cu (nm) | electrode | (mAcm⁻²) | (mV) | (%) | (%) |
| 0 | 1.1 | Ni | 20.2 | 500 | 63.8 | 6.4 |
| 25 | 1.1 | Ni | 21.2 | 710 | 59.7 | 9.0 |
| 50 | 1.1 | Ni | 21.4 | 780 | 73.7 | 12.3 |
| 100 | 1.1 | Ni | 21.3 | 810 | 73.6 | 12.7 |
| 200 | 1.1 | Ni | 21.3 | 800 | 76.8 | 13.1 |
| 300 | 1.1 | Ni | 22.0 | 810 | 75.6 | 13.5 |

TABLE 3
Device performances of CdS/CdTe cells with different thickness of Cu.

| Back contact buffer | | Back contact | Jsc | Voc | FF | η |
|---|---|---|---|---|---|---|
| Te (nm) | Cu (nm) | electrode | (mAcm⁻²) | (mV) | (%) | (%) |
| 100 | 9.0 | Ni | 21.9 | 800 | 73.0 | 12.8 |
| 100 | 4.5 | Ni | 21.5 | 815 | 74.3 | 13.0 |
| 100 | 2.2 | Ni | 21.7 | 820 | 74.4 | 13.3 |
| 100 | 1.1 | Ni | 21.8 | 810 | 75.4 | 13.3 |
| 100 | 0.6 | Ni | 22.0 | 810 | 74.7 | 13.3 |
| 100 | 0.3 | Ni | 21.9 | 810 | 75.0 | 13.3 |
| 100 | 0.0 | Ni | 21.4 | 800 | 71.0 | 12.1 |

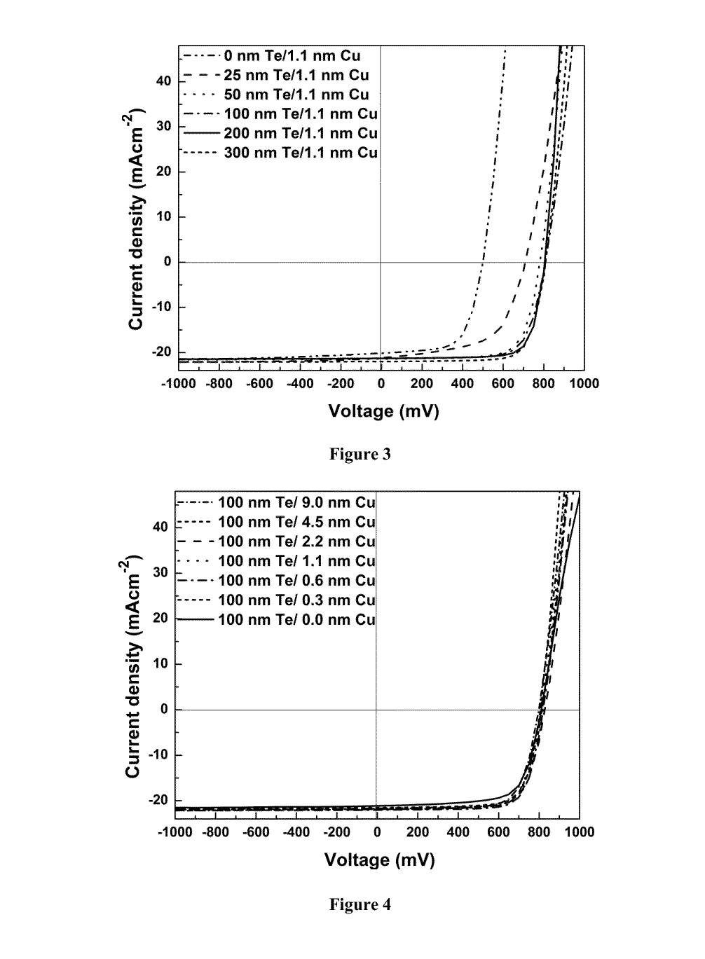

The current-voltage (J-V) characteristics of CdS/CdTe cells were measured using the same procedure described in Example 1. FIG. 3 exhibit the photo J-V characteristics of CdS/CdTe cells with different thickness of Te. The device performances are listed in Table 2. Compared with the cell without Te buffer layer, the cells with a Te layer with a thickness ranging from 50 nm to 300 nm show significant improvements, indicating the Te buffer layer is critical.

FIG. 4 exhibit the photo J-V characteristics of CdS/CdTe cells with different thickness of Cu. The device performances are listed in Table 3. The thickness of Cu does not affect the device performance of the cell too much. The optimum thickness of Cu is between 0.6 to 4.5 nm.

### EXAMPLE 3

This example shows the effects of annealing conditions on device performances of CdS/CdTe cells.

CdS/CdTe cells were fabricated according to the same procedure as Example 1 except for step e, which was modified as follows: e) After VCC treatment, a layer of 100-nm Te and a layer of 9.0-nm Cu were deposited in sequence on top of CdTe by DC sputtering. The cell was completed by depositing a layer of 200-nm Ni on top of Te/Cu buffer layer. In the end, the cell was subjected to a temperature between 100 and 200° C. for a duration of 20 minutes or at 100° C. for a duration up to 60 minutes in N₂ ambient.

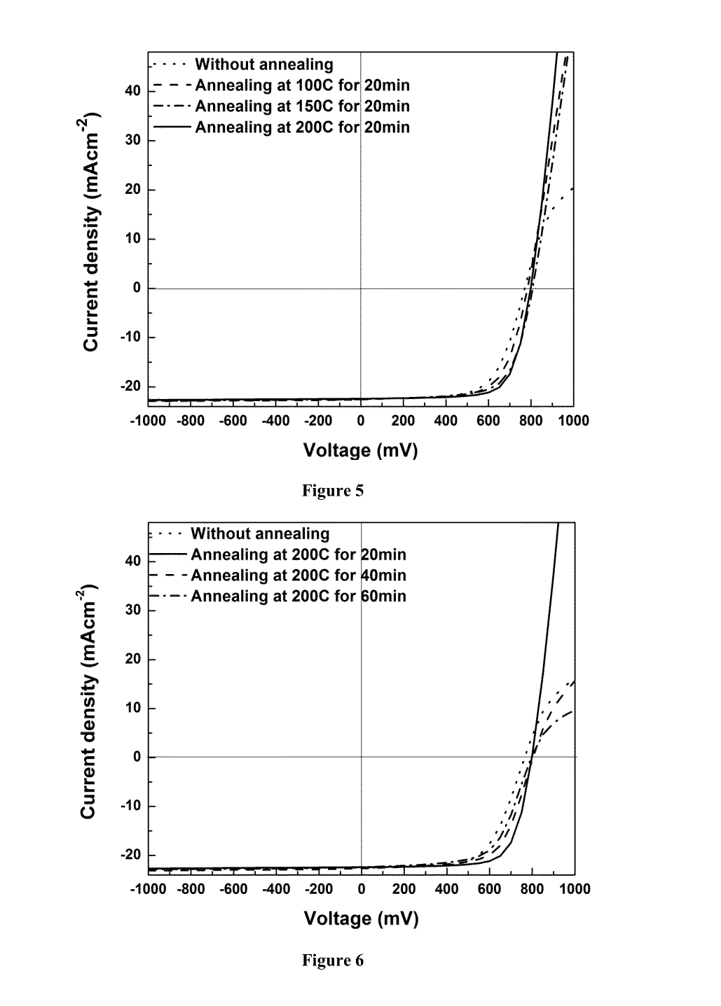

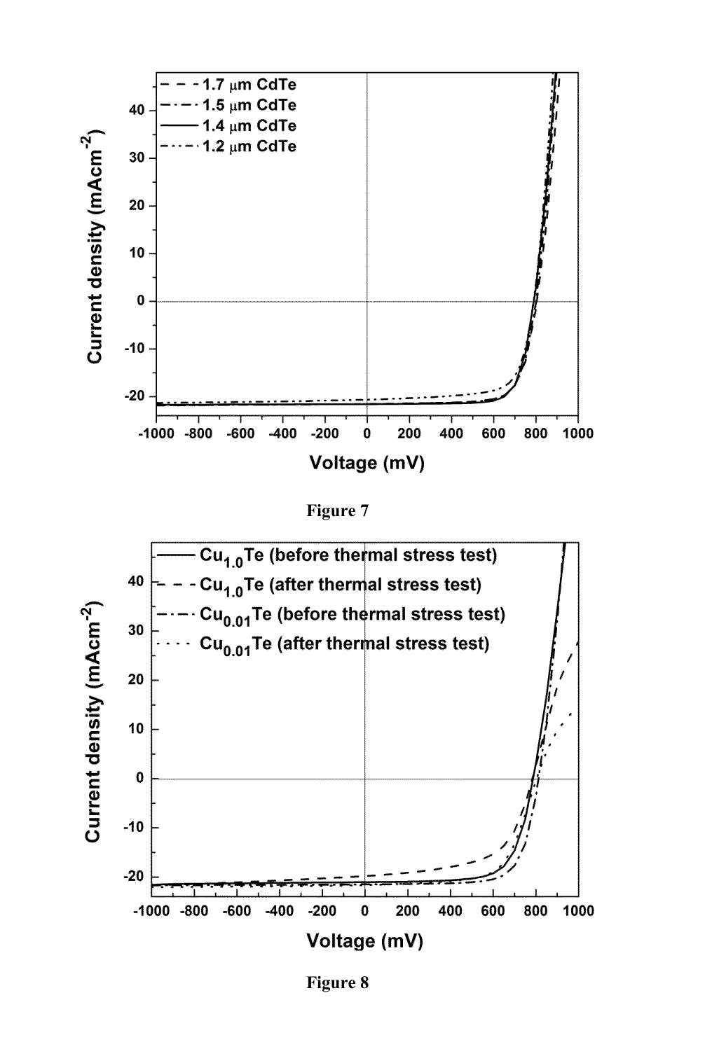

The current-voltage (J-V) characteristics of CdS/CdTe cells were examined using the same procedure described in Example 1. FIG. 5 and FIG. 6 exhibit the photo J-V characteristics of CdS/CdTe cells annealed at different temperature and for different duration respectively. The device performances of these cells are listed in Table 4.

TABLE 4
Device performances of CdS/CdTe cells annealed at
different temperature or for different duration

| Annealing | Annealing | Jsc | Voc | FF | η |
|---|---|---|---|---|---|
| Temperature (° C.) | Duration (min) | (mAcm⁻²) | (mV) | (%) | (%) |
| None | None | 22.5 | 770 | 63.6 | 11.0 |
| 100 | 20 | 22.6 | 780 | 68.4 | 12.1 |
| 150 | 20 | 22.5 | 807 | 69.2 | 12.6 |
| 200 | 20 | 22.4 | 800 | 73.0 | 13.1 |
| 200 | 40 | 22.6 | 805 | 65.6 | 11.9 |
| 200 | 60 | 22.4 | 790 | 64.4 | 11.4 |

As FIG. 5 shows, compared with the cell without annealing, the cells annealed at a temperature between 100 and 200° C. show improved contact. There is no roll-over for the cell with annealing. In general, the cell efficiency can be improved by 6 to 15% after the cell was annealed at a temperature between 100 and 200° C. for 20 minutes. As FIG. 6 shows, compared with the cell without annealing, the cell annealed at 200° C. for 20 minutes exhibits improved contact and an increase of 19% in cell efficiency. However, as the annealing duration increased from 20 to 60 minutes, the cell efficiency decreases. Other experimental results showed as the Cu/Te ratio decreases, the stability of cell became much better while the initial device performance was still good.

### EXAMPLE 4

This example shows the application of Te/Cu back contact buffer in ultra-thin CdS/CdTe cells.

CdS/CdTe cells were fabricated according to the same procedure as Example 1 except for step c, which are modified as follows: c) A layer of CdTe film with a thickness ranging from 1.2 to 1.7 μm was deposited by CSS method.

The current-voltage (J-V) characteristics of CdS/CdTe cells were examined using the same procedure described in Example 1. FIG. 7 exhibits the J-V characteristics of ultra-thin CdS/CdTe cells with different thickness of CdTe (from 1.2 to 1.7 μm). The device performances of these cells are listed in Table 5.

As the CdTe film thickness decreases from 1.2 μm to 1.7 μm, the cell performances are still acceptable.

TABLE 5
Device performances of CdS/CdTe cells
with different thickness of CdTe

| CdTe | Jsc | Voc | FF | η |
|---|---|---|---|---|
| (μm) | (mAcm⁻²) | (mV) | (%) | (%) |
| 1.7 | 21.5 | 805 | 74.1 | 12.8 |
| 1.5 | 21.6 | 800 | 74.4 | 12.9 |
| 1.4 | 21.6 | 790 | 76.5 | 13.1 |
| 1.2 | 20.7 | 790 | 70.8 | 11.6 |

### EXAMPLE 5

This example shows the effects of Cu/Te ratio on CdS/CdTe cells with Te/Cu back contact.

CdS/CdTe cells were fabricated according to the same procedure as Example 1 except for step e, which was modified as follows: e) After VCC treatment, a layer of 100-nm Te and a layer of Cu with a thickness 1.1 nm or 72 nm were deposited in sequence on top of CdTe by DC sputtering. The cell was completed by depositing a layer of 200-nm Ni on top of Te/Cu buffer layer. In the end, the cell was subjected to an annealing process at 245° C. for 20 s in N₂ ambient.

Thermal stress test was carried out on CdS/CdTe cells with Te/Cu back contact of different Cu/Te molar ratio. The CdS/CdTe cells were subjected to pure N₂ at 245° C. for 25 minutes at atmospheric pressure.

The current-voltage (J-V) characteristics of the CdS/CdTe cells were measured using the same procedure as described in Example 1. FIG. 8 shows the J-V characteristics of CdS/CdTe cells with Te/Cu back contact of different Cu to Te molar ratio after the thermal stress test. As Table 6 shows, thermal stress causes the cell with a high Cu to Te ratio to degrade more rapidly compared to the cell with a low Cu to Te ratio.

TABLE 6
Thermal stress test results of CdS/CdTe cells with
Te/Cu back contacts of different Cu/Te molar ratio

| Cu/Te | Thermal | Jsc | Voc | FF | η |
|---|---|---|---|---|---|
| molar ratio | stress test | (mAcm⁻²) | (mV) | (%) | (%) |
| 1.0 | Before | 21.1 | 785 | 70.2 | 11.6 |
| 1.0 | After | 19.8 | 780 | 57.6 | 8.9 |
| 0.03 | Before | 21.5 | 810 | 73.4 | 12.8 |
| 0.03 | After | 21.6 | 805 | 65.6 | 11.4 |

### EXAMPLE 6

This example shows the thermal stability of CdS/CdTe cell with Te/Cu and Te back contacts.

TABLE 7
Thermal stress test (TST) results of CdS/CdTe cells with Te/Cu and Te back contacts.

| | Te (100 nm)/Cu (0.3 nm) | | | | Te (100 nm) | | | |
|---|---|---|---|---|---|---|---|---|
| TST duration | Jsc | Voc | FF | η | Jsc | Voc | FF | η |
| (h) | (mAcm⁻²) | (mV) | (%) | (%) | (mAcm⁻²) | (mV) | (%) | (%) |
| 0 | 22.5 | 820 | 75.3 | 13.9 | 22.2 | 810 | 74.0 | 13.3 |
| 1 | 22.5 | 820 | 74.2 | 13.7 | 22.0 | 805 | 72.1 | 12.8 |
| 3 | 22.5 | 820 | 74.0 | 13.6 | 21.8 | 805 | 70.4 | 12.4 |
| 6 | 22.5 | 825 | 74.0 | 13.7 | 21.6 | 790 | 67.2 | 11.5 |
| 9 | 22.4 | 828 | 72.5 | 13.4 | 21.6 | 780 | 66.8 | 9.7 |

CdS/CdTe cells were fabricated according to the same procedure as Example 1 except for step e, which was modified as follows: e) After VCC treatment, a layer of 100-nm Te and a layer of Cu with a thickness 0.3 nm were deposited in sequence on top of CdTe by DC sputtering. For the reference cell, only 100-nm Te was deposited on top of CdTe. The cells were completed by depositing a layer of 200-nm Ni on top of Te/Cu buffer layer. In the end, the cell was subjected to an annealing process at 245° C. for 20 seconds in N₂ ambient.

Thermal stress test was carried out on CdS/CdTe cells with Te/Cu back contact of a Cu/Te molar ratio of 0.01. The CdS/CdTe cells were subjected to pure N₂ at 200° C. for 0˜9 hours at atmospheric pressure.

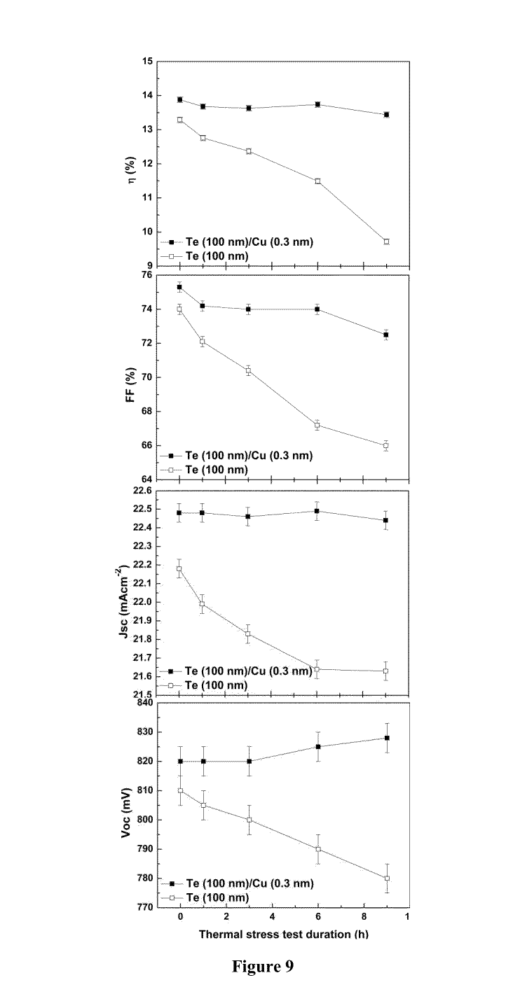

The current-voltage (J-V) characteristics of the CdS/CdTe cells were measured using the same procedure as described in Example 1. FIG. 9 shows the device performance of CdS/CdTe cells with Te/Cu or Te back contact buffer before and after thermal stress test. As Table 7 shows, with a low Cu to Te ratio of 0.01, CdS/CdTe cell with Te/Cu back contact degraded only by 3.2% after 9 hours of thermal stress test. But the cell with just Te back contact degraded by 26.9%.

While the invention has been particularly shown and described with reference to specific embodiments (some of which are preferred embodiments), it should be understood by those having skill in the art that various changes in form and detail may be made therein without departing from the spirit and scope of the present invention as disclosed herein.

What is claimed is:

1. A photovoltaic cell comprising a p-type semiconductor material having a thickness of 0.5 microns to 2 microns, a back contact buffer material in contact with the p-type semiconductor material, and a back electrode material in contact with the back contact buffer layer, wherein the back contact buffer material comprises tellurium and copper.

2. The photovoltaic cell of claim 1, wherein the p-type semiconductor material, the back contact buffer material, and the back electrode material are present as layers, and the photovoltaic cell further comprises:
a substrate, wherein the substrate is at least semitransparent;
a front electrode layer, wherein the front electrode is at least semitransparent;
optionally, a front buffer layer; and
an n-type semiconductor layer; and
the sequence of the components of the photovoltaic cell is:
a) the substrate;
b) the front electrode;
c) optionally, the front buffer layer;
d) the n-type semiconductor layer;
e) the p-type semiconductor layer;
f) the back contact buffer layer; and
g) the back electrode.

3. A photovoltaic cell as in claim 2, wherein the n-type semiconductor layer is cadmium sulfide or a cadmium sulfide alloy.

4. A photovoltaic cell as in claim 2, wherein the p-type semiconductor layer is cadmium telluride.

5. A photovoltaic cell as in claim 2, wherein the back electrode layer is a metal film, wherein the metal is selected from the group consisting of nickel, molybdenum, chromium and stainless steel.

6. A photovoltaic cell as in claim 2, wherein the back contact buffer layer comprises a discrete layer of tellurium and a discrete layer of copper.

7. A photovoltaic cell as in claim 6, wherein the tellurium layer is adjacent to the cadmium telluride layer.

8. A photovoltaic cell as in claim 6, wherein the thickness of the tellurium layer is 10 nanometers to 1000 nanometers and/or the thickness of the copper layer is 0.03 nanometers to 10 nanometers.

9. A photovoltaic cell as in claim 1, wherein the back contact buffer layer is deposited by a physical deposition method selected from the group consisting of sputtering, e-beam evaporation, and resistive heating evaporation.

10. A photovoltaic cell as in claim 1, wherein the molar ratio of copper to tellurium in the back contact buffer material is from 1×10⁻⁴ to 0.3.

11. A photovoltaic cell comprising a p-type semiconductor material, a back contact buffer material in contact with the p-type semiconductor material, and a back electrode in contact with the buffer material, wherein the buffer material comprises tellurium and copper, wherein the ratio of copper to tellurium molar ratio is from 1×10⁻⁴ and 0.3.

12. The photovoltaic cell of claim 11, wherein the p-type semiconductor material, the back contact buffer material, and the back electrode material are present as layers, and the photovoltaic cell further comprises:
a substrate, wherein the substrate is at least semitransparent;
a front electrode layer, wherein the front electrode is at least semitransparent;
optionally, a front buffer layer; and
an n-type semiconductor layer; and
the sequence of the components of the photovoltaic cell is:
a) the substrate;
b) the front electrode;
c) optionally, the front buffer layer;
d) the n-type semiconductor layer;
e) the p-type semiconductor layer;
f) the back contact buffer layer; and
g) the back electrode.

13. A photovoltaic cell as in claim 12, wherein the n-type semiconductor layer is cadmium sulfide or a cadmium sulfide alloy.

14. A photovoltaic cell as in claim 12, wherein the p-type semiconductor layer is cadmium telluride and the p-type semiconductor layer is deposited by close-space sublimation.

15. A photovoltaic cell as in claim 12, wherein the back electrode is a metal film, wherein the metal is selected from the group consisting of nickel, molybdenum, chromium and stainless steel.

16. A photovoltaic cell as in claim 12, wherein the back contact buffer layer comprises a discrete layer of tellurium and a discrete layer of copper.

17. A photovoltaic cell as in claim 16, wherein the tellurium layer is adjacent to the p-type semiconductor layer.

18. A photovoltaic cell as in claim 16, wherein the thickness of the tellurium layer is 10 nanometers to 1000 nanometers and/or the thickness of the copper layer is 0.03 nanometers to 10 nanometers.

19. A photovoltaic cell as in claim 12, wherein the back contact buffer layer is deposited by a physical deposition method selected from the group consisting of sputtering, e-beam evaporation, and resistive heating evaporation.
